(19) United States
(12) Patent Application Publication
(10) Pub. No.: US 2025/0073560 A1
(43) Pub. Date: Mar. 6, 2025

(54) GOLF SIMULATION METHOD AND ELECTRONIC APPARATUS AND SERVER PROVIDING THE SAME

(71) Applicant: VC INC., Seoul (KR)

(72) Inventors: Ki Tae KIM, Seongnam-si (KR); Hakyong Lee, Yongin-si (KR)

(21) Appl. No.: 18/723,973

(22) PCT Filed: Nov. 16, 2022
(86) PCT No.: PCT/KR2022/018077

§ 371 Date: Jun. 25, 2024

(30) Foreign Application Priority Data
Dec. 29, 2021 (KR) 10-2021-0191328

(51) Int. Cl. A63B 71/06; A63B 24/00; A63B 69/36

(52) U.S. Cl. CPC A63B 71/0622; A63B 24/0021; A63B 69/36; A63B 2024/004; A63B 2071/0636

(57) ABSTRACT

Disclosed is a golf simulation method including: displaying an image of a first view of a green of a virtual golf course; displaying an image of a second view of the green having a viewpoint different from the first view; and receiving a selection of one point on the green in the image of the first view or the image of the second view.

### TECHNICAL FIELD

The present disclosure relates to a golf simulation method and an electronic apparatus and a server for providing the same.

### BACKGROUND ART

The game of golf is typically played on a golf course designed for golf. For ordinary people who are not golfers, practicing swing and putting on a golf course is limited by time, space, and cost. Therefore, various devices for practicing golf have been introduced in recent years.

For swing using drivers, woods, and irons, the struck golf ball travels while flying, so the distance and direction of the golf ball's travel is less affected by the terrain. That is, golfers may practice their swings without considering the terrain.

In contrast to this, in a case of putting with a putter, a struck golf ball travels while rolling on the ground, so the distance and direction of the golf ball's travel is greatly influenced by the terrain. However, existing putting practice devices only provide a practice method to improve the user's putting ability by detecting whether the putter head strikes the golf ball accurately or not during putting, or by estimating the putting distance according to the putting stroke, but existing putting practice devices cannot improve the ability to analyze the terrain of the green.

### DISCLOSURE

### Technical Problem

The present disclosure attempts to solve the foregoing problems and other problems.

The present disclosure attempts to provide a golf simulation method of enabling a user to learn breaks on a green, and an electronic apparatus and a server for providing the same.

The present disclosure attempts to provide a golf simulation method of allowing a user to practice putting, and an electronic apparatus and a server for providing the same.

### Technical Solution

An exemplary embodiment of the present disclosure provides a golf simulation method including: displaying an image of a first view of a green of a virtual golf course; displaying an image of a second view of the green having a viewpoint different from the first view; and receiving a selection of one point on the green in the image of the first view or the image of the second view.

The first view and the second view may include two different views from a top view of the green, a view looking at a hole cup on the green from a first point on the green, a view looking at the hole cup from a second point located opposite the first point with respect to the hole cup along an extension line connecting the first point and the hole cup, and a view looking at the first point and the hole cup from a third point forming a predetermined angle with the extension line with respect to the hole cup.

The first view and/or the second view may include a view at a first height or a second height with respect to the ground at each point.

The first view and/or the second view may further display a grid pattern on the green.

The golf simulation method may further include calculating a result of an evaluation for the one point on the green.

The calculating of the result of the evaluation for the one point on the green may include: performing a simulation in which a golf ball on the green is holed into a hole cup, and determining whether a trajectory of the golf ball calculated from the simulation passes through the one point on the green; and determining, when the trajectory of the golf ball passes through the one point on the green, whether a direction of travel of the golf ball changes at or near the one point on the green.

The golf simulation method may further include calculating a target distance from a golf ball on the green to the one point on the green.

The golf simulation method may further include: displaying an image of a view looking at the one point on the green from a golf ball on the green; sensing a golf ball putted by a user; determining a movement of the sensed golf ball; and simulating a golf ball on the green based on the movement of the sensed golf ball.

Another embodiment of the present disclosure provides an electronic apparatus including: a display unit; a user input unit; and a control unit for displaying an image of a first view of a green of a virtual golf course on the display unit, displaying an image of a second view of the green having a viewpoint different from the first view on the display unit, and receiving a selection of one point on the green in the image of the first view or the image of the second view through the user input unit.

The first view and the second view may include two different views from a top view of the green, a view looking at a hole cup on the green from a first point on the green, a view looking at the hole cup from a second point located opposite the first point with respect to the hole cup along an extension line connecting the first point and the hole cup, and a view looking at the first point and the hole cup from a third point forming a predetermined angle with the extension line with respect to the hole cup.

The first view and/or the second view may include a view at a first height or a second height with respect to the ground at each point.

The first view and/or the second view may further display a grid pattern on the green.

The control unit may calculate a result of an evaluation for one point on the green.

The control unit may perform performing a simulation in which a golf ball on the green is holed into a hole cup, and determine whether a trajectory of the golf ball calculated from the simulation passes through the one point on the green, and determine, when the trajectory of the golf ball passes through the one point on the green, whether a direction of travel of the golf ball changes at or near the one point on the green to calculate the result of the evaluation.

The control unit may calculate a target distance from a golf ball on the green to the one point on the green.

The control unit may display an image of a view looking at the one point on the green from a golf ball on the green.

The electronic apparatus may further include a sensing unit for sensing a golf ball putted by a user, in which the control unit may determine a movement of the sensed golf ball, and simulates a golf ball on the green based on the movement of the sensed golf ball.

Still another embodiment of the present disclosure provides a server including a communication unit, a memory, and a control unit, in which the control unit executes instructions stored in the memory to perform the method, and displays the executed instructions on an electronic apparatus communicating through the communication unit.

### Advantageous Effects

The golf simulation method, and the electronic apparatus and the server providing the same according to the present disclosure have the effects described as follows.

According to at least one of the embodiments of the present disclosure, it is possible to improve a user's green target ability.

Further, according to at least one of the embodiments of the present disclosure, it is possible to improve a user's putting ability.

The additional scope of applicability of the present disclosure will become apparent from the following detailed description. However, it should be understood that the detailed description and specific embodiments, such as the exemplary embodiment of the present disclosure, are given by way of illustration only, since various changes and modifications within the scope of the present disclosure may be clearly understood by those skilled in the art.

### DESCRIPTION OF THE DRAWINGS

FIG. 1 is a block diagram illustrating an electronic apparatus according to an embodiment.

FIG. 2 is a flowchart illustrating a part of a golf simulation method according to an embodiment.

FIGS. 3 to 7 are diagrams illustrating screens displayed on the electronic apparatus in accordance with the golf simulation method of FIG. 2.

FIG. 8 is a flowchart illustrating another part of the golf simulation method according to the embodiment.

FIG. 9 is a diagram illustrating an example of simulating putting according to the golf simulation method of FIG. 8.

FIG. 10 is a diagram illustrating a server according to an embodiment.

### MODE FOR INVENTION

Hereinafter, an exemplary embodiment disclosed the present specification will be described in detail with reference to the accompanying drawings, and the same or similar constituent factor is denoted by the same reference numeral regardless of a reference numeral, and a repeated description thereof will be omitted. Suffixes, “module” and “unit” for a component used for the description below are given or mixed in consideration of only easiness of the writing of the specification, and the suffix itself does not have a discriminated meaning or role. Further, in describing the exemplary embodiment disclosed in the present disclosure, when it is determined that detailed description relating to well-known functions or configurations may make the subject matter of the exemplary embodiment disclosed in the present disclosure unnecessarily ambiguous, the detailed description will be omitted. Further, the accompanying drawings are provided for helping to easily understand exemplary embodiments disclosed in the present specification, and the technical spirit disclosed in the present specification is not limited by the accompanying drawings, and it will be appreciated that the present disclosure includes all of the modifications, equivalent matters, and substitutes included in the spirit and the technical scope of the present disclosure.

Terms including an ordinary number, such as first and second, are used for describing various components, but the components are not limited by the terms. The terms are used only to discriminate one component from another component.

It should be understood that when one component referred to as being “coupled to” or “connected to” another component, one component may be directly coupled to or connected to the other component, but intervening elements may also be present. By contrast, when one component is referred to as being “directly coupled to” or “directly connected to” another component, it should be understood that there are no intervening elements.

A singular expression includes a plural expression unless it is specifically described to the contrary in the context.

In the present application, it will be appreciated that terms “including” and “having” are intended to designate the existence of characteristics, numbers, operations, operations, components, and components described in the specification or a combination thereof, and do not exclude a possibility of the existence or addition of one or more other characteristics, numbers, operations, operations, components, and components, or a combination thereof in advance.

Electronic apparatuses described in the present specification may include cell phones, smart phones, laptop computers, digital broadcast terminals, personal digital assistants (PDAs), portable multimedia players (PMPs), navigation, slate PCs, tablet PCs, ultrabooks, wearable devices (for example, smartwatches, smart glasses, head mounted displays (HMDs), and the like.

However, it will be readily apparent to those skilled in the art that the configurations according to the embodiments described in the present specification may also be applied to fixed terminals, such as digital TVs, desktop computers, digital signage, and the like, except that they are applicable only to electronic apparatuses.

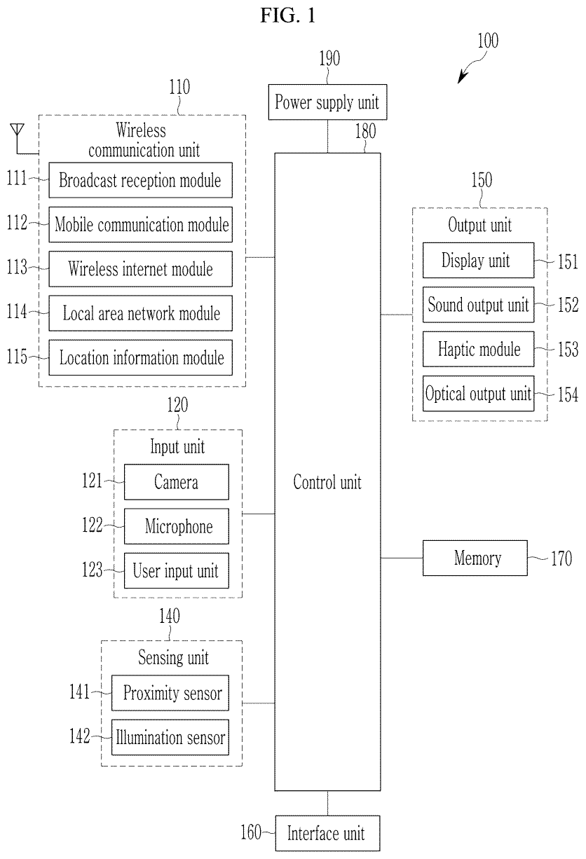

FIG. 1 is a block diagram illustrating an electronic apparatus according to an embodiment.

The electronic apparatus 100 may include a wireless communication unit 110, an input unit 120, a sensing unit 140, an output unit 150, an interface unit 160, a memory unit 170, a control unit 180, and a power supply unit 190. The components shown in FIG. 1 are not essential to implement an electronic apparatus, and the electronic apparatus described in the present specification may have more or fewer components than those listed above.

More specifically, of the above components, the wireless communication unit 110 may include one or more modules that enable wireless communication between the electronic apparatus 100 and a wireless communication system, between the electronic apparatus 100 and another electronic apparatus 100, or between the electronic apparatus 100 and an external server. Further, the wireless communication unit 110 may include one or more modules that connect the electronic apparatus 100 to one or more networks.

The wireless communication unit 110 may include at least one of a broadcast reception module 111, a mobile communication module 112, a wireless internet module 113, a local area network module 114, and a location information module 115.

The input unit 120 may include a camera 121 or an image input unit for inputting an image signal, a microphone 122 or an audio input unit for inputting an audio signal, and a user input unit 123 (for example, a touch key or a mechanical key) for receiving information from a user. Voice data or image data collected at the input unit 120 may be analyzed and processed into control commands of the user.

The input unit 120 is for inputting image information (or signals), audio information (or signals), data, or information input from a user, and for inputting image information, the electronic apparatus 100 may be provided with one or more cameras 121. For example, the plurality of cameras 121 provided in the electronic apparatus 100 may be arranged to form a matrix structure, and through the cameras 121 forming the matrix structure, a plurality of image information having various angles or focal points may be input to the electronic apparatus 100. Further, the plurality of cameras 121 may be arranged in a stereo structure to acquire left and right images for recognizing objects in the surrounding space.

Further, in the camera 121, various hardware or sensors to assist with photographing may be additionally disposed. For example, the camera 121 may further include a distance sensor (for example, a TOF sensor) to detect the distance between a subject and the electronic apparatus 100.

The sensing unit 140 may include one or more sensors for sensing at least one of information within the electronic apparatus, neighboring environmental information surrounding the electronic apparatus, and user information. For example, the sensing unit 140 may include at least one of a proximity sensor 141, an illumination sensor 142, a touch sensor, an acceleration sensor, a magnetic sensor, a gravity sensor (G-sensor), a gyroscope sensor, a motion sensor, an RGB sensor, an infrared sensor (IR sensor), a finger scan sensor, an ultrasonic sensor, an optical sensor (for example, the camera (see reference numeral 121)), a microphone (see reference numeral 122), a gauge, an environmental sensor (for example, a barometer, a hygrometer, a thermometer, a radiation detection sensor, a heat detection sensor, and a gas detection sensor), and a chemical sensor (for example, an electronic nose, a healthcare sensor, and a biometric sensor). In the meantime, the electronic apparatus disclosed in the present specification may utilize a combination of information sensed by at least two of these sensors.

The sensing unit 140 may include a radar sensor. The radar sensor includes a signal source and a plurality of antennas. The radar sensor may be a Doppler radar. The plurality of antennas is spaced in a vertical direction, and when a signal emitted from the signal source is reflected from an object, the plurality of antennas receives the signal. Using the signal received from the plurality of antennas, the radar sensor may measure a distance between an object in front of the radar sensor (described herein as a ball, but also including, without limitation, a golf club) and the radar sensor.

The output unit 150 is for generating outputs related to visual, auditory, or tactile sensations, and may include at least one of a display unit 151, a sound output unit 152, a haptic module 153, and an optical output unit 154. The display unit 151 may have an interlayer structure or be integrally formed with the touch sensor to implement a touch screen. The touch screen may function as the user input unit 123 to provide an input interface between the electronic apparatus 100 and a user, and may also provide an output interface between the electronic apparatus 100 and a user.

The interface unit 160 serves as a passage for various types of external devices that are connected to the electronic apparatus 100. The interface unit 160 may include at least one of a wired/wireless headset port, an external charger port, a wired/wireless data port, a memory card port, a port for connecting a device provided with an identification module, an audio I/O port, a video I/O port, and an earphone port. In response to the connection of the external device to the interface unit 160, the electronic apparatus 100 may perform appropriate controls associated with the connected external device.

In addition, the memory 170 stores data that supports various functions of the electronic apparatus 100. For example, the memory 170 may store all data necessary for implementing an image of a golf simulation, and may store data about a virtual golf course implemented by imaging a real golf course, data about terrain information of the virtual golf course, and the like, to provide data that may implement a virtual environment that allows a virtual round of golf to be played on the virtual golf course.

The memory 170 may store a number of applications (application programs or applications) running on the electronic apparatus 100, and data and instructions for operating the electronic apparatus 100. At least some of the application programs may be downloaded from an external server through wireless communication. In addition, at least some of the application programs may be present on the electronic apparatus 100 from the factory for basic functionality of the electronic apparatus 100 (for example, the ability to receive and make calls, and the ability to receive and send messages). In the meantime, the application program may be stored in the memory 170 and is installed in the electronic apparatus 100 to be driven so that the operation (or function) of the electronic apparatus is performed by the control unit 180.

In addition to the operation related to the application program, the control unit 180 may generally control the general operation of the electronic apparatus 100. The control unit 180 may process the signal, the data, the information, and the like input or output through the foregoing components or drive the application program stored in the memory 170 to provide the appropriate information or function to the user or process the appropriate information or function. For example, the control unit 180 performs information processing to implement an image of the virtual golf course on the screen by using data about the virtual golf course stored in the memory 170, and performs information processing to implement an image in which a trajectory of the golf ball struck by the user is simulated on the virtual golf course.

Further, the control unit 180 may control at least some of the components described with reference to FIG. 1 in order to drive the application program stored in the memory 170. Further, the control unit 180 may operate at least two of the components included in the electronic apparatus 100 in combination with each other to drive the application program.

The power supply unit 190, under the control of the control unit 180, receives power from an external power source and an internal power source and provides power to each of the components included in the electronic apparatus 100. The power supply unit 190 includes a battery, and the battery may be an embedded battery or a replaceable battery.

At least some of each of the components may operate in cooperation with each other to implement the operation of the electronic apparatus, the control, or the control method of the electronic apparatus according to various embodiments which will be described below. Further, the operation, the control, or the control method of the electronic apparatus may be implemented on the electronic apparatus for driving at least one application program stored in the memory 170.

In the following, embodiments relating to a golf simulation method that may be implemented in the electronic apparatus configured as described above will be described with reference to the accompanying drawings. It will be apparent to those skilled in the art that the present disclosure may be embodied in other specific forms without departing from the spirit and essential features of the present disclosure.

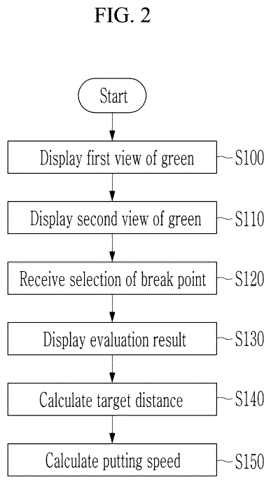

FIG. 2 is a flowchart illustrating a part of a golf simulation method according to an embodiment.

Referring to FIG. 2, the control unit 180 displays a first view image of a green of a virtual golf course on the display unit 151 (S100). Further, the control unit 180 displays a second view image of the green of the virtual golf course on the display unit 151 (S110). The first view image of the green and the second view image of the green are images of the same green viewed from different viewpoints.

The first view and the second view may each include at least one view selected from two groups of (1) to (4) below. That is, in each of operation S100 and operation S110, the control unit 180 may display at least one view on the display unit 151.
(1) A top view of the green (including views looking at the green from multiple heights above the ground on the green)
(2) A view looking at the hole cup on the green from a first height from a first point on the green, and a view looking at the hole cup from a second height lower than the first height from the first point (where the first point may be the location of the golf ball on the green of the virtual golf course)
(3) A view looking at the hole cup at the first height from a second point located opposite the first point with respect to the hole cup along an extension line connecting the first point and the hole cup, and a view looking at the hole cup from the second height at the second point
(4) A view looking at the first point and the hole cup from the first height at a third point that forms a predetermined angle (greater than 0 degrees and less than 180 degrees) with the extension line connecting the first point and the hole cup with respect to the hole cup, and a view looking at the first point and the hole cup at the from the second height at the third point

The first height may be a height between 100 cm and 200 cm from the ground level at the corresponding point, and the second height may be a height between 5 cm and 100 cm with respect to the ground at the corresponding point.

When displaying the first view and/or the second view, the control unit 180 may further display visual means (a grid pattern and the like) that may be helpful in recognizing the slope of the green, the height of the terrain, and the like.

The control unit 180 receives an input for selecting a break point, which is input through the user input unit 123 (S120). For example, in the state where the first view or second view displayed on the display unit 151, the user may select a break point on the green that is recognized based on the terrain shape of the green, shading, grass texture, and the like.

The break point is the point at which a direction of the slope is predicted to be changed as the golf ball progresses to the hole cup, and is determined by the terrain of the green. It is difficult to determine the break point only from a single viewpoint. This is because the shading of the green varies depending on the user's location on the green when viewing the green, and the terrain may have a complex shape with repeated ups and downs, so that it is difficult for the user to accurately recognize the slope of the green through only a visual image from a single point.

According to the golf simulation method according to the present disclosure, a plurality of views from different locations is displayed, thereby having the effect of enabling a user to learn a routine for recognizing break points on a green.

Next, the control unit 180 displays a result of an evaluation of the point selected by the user (S130). The control unit 180 may perform various simulations in which a golf ball located at the first point is holed into the hole cup, and determine whether a trajectory of the golf ball calculated in each simulation passes through the point selected by the user. When the trajectory of the golf ball passes through the point selected by the user, the control unit 180 may determine whether the direction of travel of the golf ball changes at or near the point selected by the user. The control unit 180 may calculate the result of the evaluation based on whether the trajectory of the golf ball calculated in each simulation passes through the point selected by the user and whether the direction of travel of the golf ball changes at or near the point selected by the user. For example, when the trajectory of the golf ball passes through the point selected by the user and the direction of travel of the golf ball changes at or close to the point selected by the user, a result score may be calculated higher.

In the above, the user selects a break point and the control unit 180 evaluates the break point, but the user may also input an estimated trajectory of the golf ball into the first view or the second view, and the control unit 180 may calculate a result based on whether the estimated trajectory matches the trajectory of the golf ball calculated in the simulation. In other words, the golf simulation method according to the present embodiment may receive various inputs to identify a break point and evaluate the break point.

Next, the control unit 180 calculates a target distance from the first point to the break point (S140) and calculates a putting speed reflecting a green speed (S150). The green speed may be set by the temperature, humidity, type of green grass, grass texture, and the like on the virtual golf course.

Here, operations S130 to S150 may be performed simultaneously.

Then, the control unit 180 may store information about the user's selected break point on the corresponding green, target distance, putting speed, and the like in the memory 170.

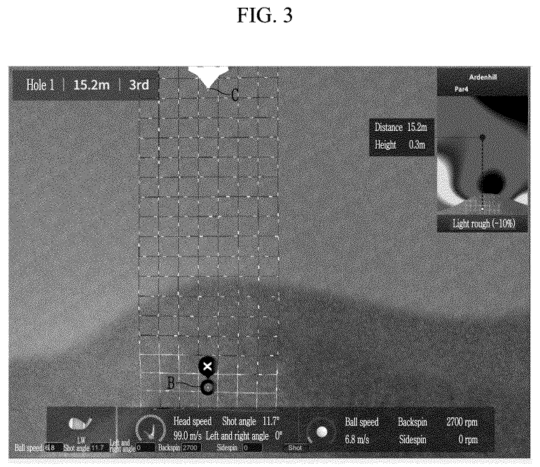

Referring to FIGS. 3 to 7, a screen displayed on the display unit 151 will be described.

FIGS. 3 to 7 are diagrams illustrating screens displayed on the electronic apparatus in accordance with the golf simulation method of FIG. 2.

FIG. 3 illustrates a top view of a green, where the green is viewed from a predetermined height above the ground of the green. In the top view of the green, the planar shape of the green and the locations of the first point B (location of the golf ball) and the hole cup C may be identified.

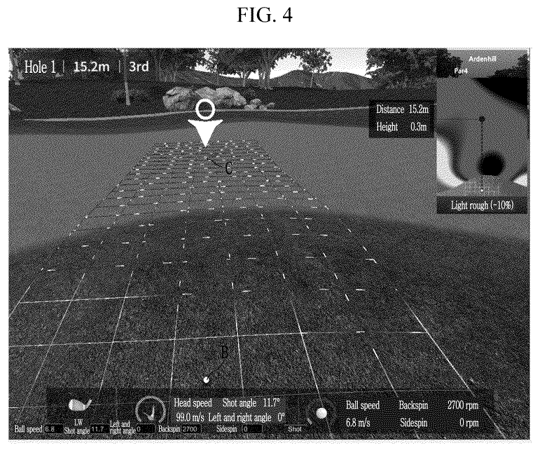

FIG. 4 illustrates a view looking at the hole cup C from the first height at the first point B on the green.

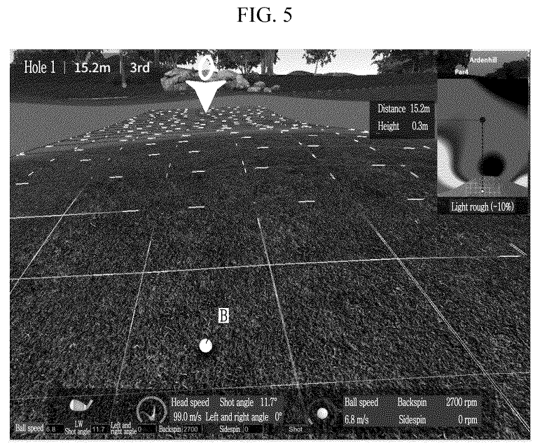

FIG. 5 illustrates a view looking at the hole cup C from the second height that is lower than the first height from the first point B on the green.

As shown in FIGS. 4 and 5, the recognized shading, shape of the terrain, and the like are different when viewing the hole cup C from the first height and the second height, even from the same first point B.

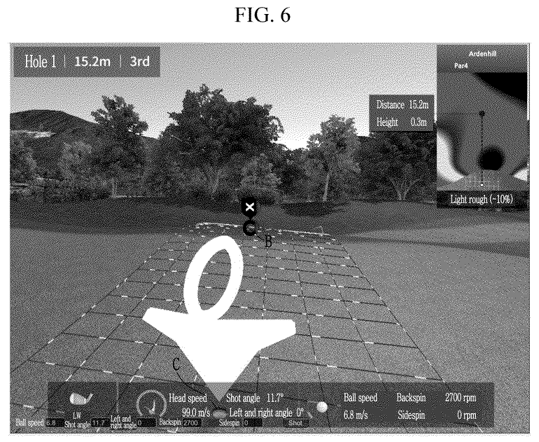

FIG. 6 illustrates a view looking at the hole cup C from the first height at the second point located opposite the first point B with respect to the hole cup C along an extension line connecting the hole cup C to the first point B on the green.

As shown in FIGS. 4 and 6, viewing the hole cup C and the golf ball (point B where the golf ball is located) from different viewpoints facilitates the recognition of the terrain between the two points.

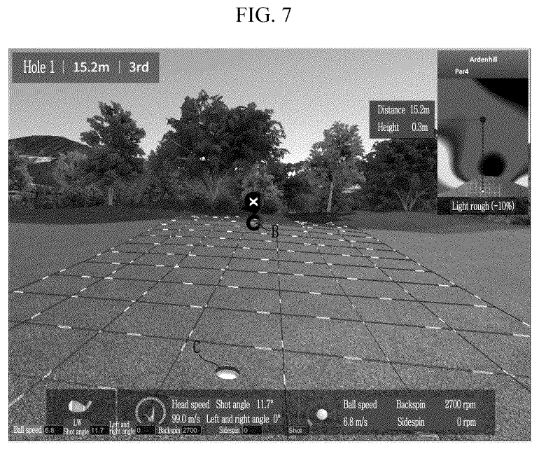

FIG. 7 illustrates a view looking at the hole cup C from the second height at a second point on the green.

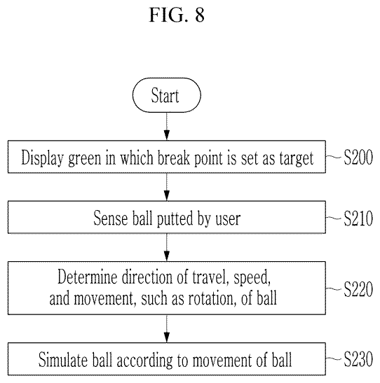

Next, referring to FIG. 8, the golf simulation method of providing a user with putting stroke practice will be described.

FIG. 8 is a flowchart illustrating another part of the golf simulation method according to the embodiment.

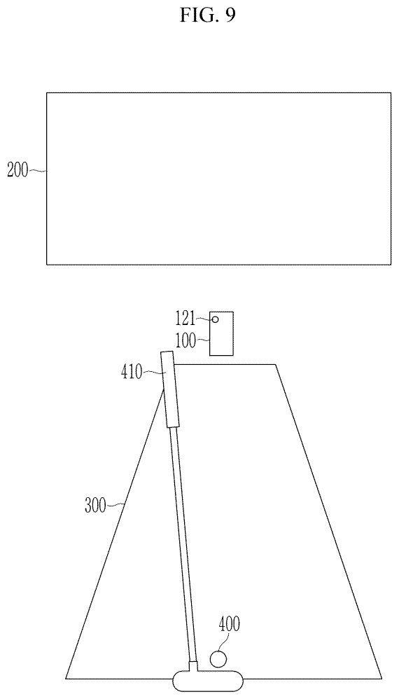

The control unit 180 displays an green image in which the brake point is set as a target (S200). For example, the control unit 180 may display the green image on the display unit 151, or may display the green image on an external display device (200 in FIG. 9) connected through the wireless communication unit 110 and/or the interface unit 160.

The green image may be an image of a view looking at the break point from the first height at the first point. The green image may display a green, a break point, a hole cup, and a golf ball.

The camera 121 and/or the sensing unit 140 senses the golf ball putted by the user (S210).

The control unit 180 determines a movement of the golf ball based on data about the golf ball sensed from the camera 121 and/or the sensing unit 140 (S220). For example, from the data about the golf ball sensed from a TOF camera, a stereoscopic camera, a radar sensor, or the like, the control unit 180 may calculate a speed of travel of the golf ball, a rotation speed of the golf ball, and a shot angle of the golf ball.

Next, the control unit 180 simulates the golf ball on the green according to the movement of the golf ball (S230). A result of the simulation is applied to the golf ball on the green and displayed.

According to the golf simulation method according to the embodiment, there is the effect in that the user practices putting directly toward the break point selected by the user, so that the user may verify through simulation whether the break point selected by the user is accurate.

FIG. 9 is a diagram illustrating an example of simulating putting according to the golf simulation method of FIG. 8.

As shown in FIG. 9, a real golf ball 400 may be located on a putting mat 300, and the electronic apparatus 100 may be located to face the golf ball 400 along the direction of travel of the golf ball 400. A user strikes the golf ball 400 by using a putter 410. The camera 121 then photographs the golf ball 400, and the electronic apparatus 100 may generate movement data of the golf ball 400 to perform a subsequent golf simulation method.

The electronic apparatus 100 may be wired or wirelessly connected to an external display device 200 to display a simulation image.

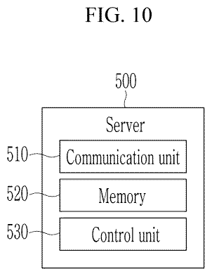

Next, a server providing a golf simulation method according to an embodiment will be described with reference to FIG. 10.

FIG. 10 is a diagram illustrating a server according to an embodiment.

Referring to FIG. 10, a server 500 includes a communication unit 510, a memory 520, and a control unit 530.

The communication unit 510 may communicate with the electronic apparatus 100 through a network.

The memory 520 may store all data necessary for implementing an image of a golf simulation, and may store data about a virtual golf course implemented by imaging a real golf course, data about terrain information of the virtual golf course, and the like, to provide data that may implement a virtual environment that allows a virtual round of golf to be played on the virtual golf course.

The control unit 530 may transmit image data to the electronic apparatus 100 through the communication unit 510, and may process the data received from the electronic apparatus 100. The control unit 530 may provide the first view and second view image data of the green to enable the electronic apparatus 100 to perform the operations S100 and S110. The control unit 530 may receive data about the break point input by the electronic apparatus 100 performing the operation S120, and perform operations S130, S140, and S150 to transmit resulting data to the electronic apparatus 100.

Further, the control unit 530 may provide image data of the green for the electronic apparatus 100 to perform operation S200. The control unit 530 may receive data about the movement of the ball determined by the electronic apparatus 100 performing operations S210 and S220, and may perform operation S230 to transmit the simulation data to the electronic apparatus 100.

The various exemplary embodiments of the present document and the terms used therein are not intended to limit the technical features described in this document to specific exemplary embodiments, and it should be understood to include various modifications, equivalents, or substitutions of the corresponding exemplary embodiment. In connection with the description of the drawings, like reference numerals may be used for similar or related components. The singular form of the noun corresponding to the item may include one or more of the item, unless the relevant context clearly dictates otherwise. In the present document, each of the terms, such as “A or B”, “at least one of A and B”, “at least one of A or B”, “A, B, or C”, “at least one of A, B, and C”, and “at least one of A, B, or C”, may include all possible combinations of items listed together in the corresponding one of the phrases. Terms, such as “first”, “second”, or “first” or “second” may simply be used to distinguish the corresponding component from other corresponding components, and do not limit the corresponding components in another aspect (for example, importance or order). When it is referred that one (for example, a first) component is “coupled” or “connected” to another component (for example, a second) with or without the terms “functionally” or communicatively”, it means that the one component may be connected to the another component directly (for example, by wire), wirelessly, or through a third component.

As used herein, the terms “module” and “unit” may include a unit implemented in hardware, software, or firmware, and are for example, interchangeable with terms, such as logic, logical block, component, or circuit. The module and the unit may be an integrally formed component or a minimum unit or a component of the part that performs one or more functions. For example, according to the exemplary embodiment, the module and the unit may be implemented in the form of an application-specific integrated circuit (ASIC).

Various exemplary embodiments of the present document may be implemented as software (for example, a program) including one or more commands stored in a storage medium (for example, an internal memory or an external memory) readable by a machine (for example, an electronic device). For example, a processor of the machine (for example, an electronic device) may call at least one command among one or more stored commands from the storage medium and execute the called command. This makes it possible for the device to be operated to perform at least one function in accordance with the called at least one command. The one or more commands may include a code generated by a compiler or a code executable by an interpreter. The machine-readable storage medium may be provided in the form of a non-transitory storage medium. Herein, the “non-transitory” only means that the storage medium is a tangible device and does not include a signal (for example, electromagnetic wave), and this terms does not discriminate the case where data is semi-permanently stored in the storage medium and the case where data is temporarily stored.

According to the exemplary embodiment, the method according to various exemplary embodiments disclosed in the present document may be included in a computer program product and provided. The computer program product may be traded between sellers and buyers as commodities. The computer program product may be distributed in the form of a machine-readable storage medium (for example, a compact disc read only memory (CD-ROM), or may be directly and on-line distributed (for example, downloaded or uploaded) through two user devices (for example, smart phones) through an application store (for example, a play store). In the case of the on-line distribution, at least some of the computer program products may be at least temporarily stored or temporarily generate in a machine-readable storage medium, such as a memory, of a server of a manufacturing company, a server of an application store, or a relay server.

According to various exemplary embodiments, each (for example, the module or the program) of the foregoing components may include single or plural objects. According to various exemplary embodiments, among the corresponding components, one or more components or operations may be omitted or one or more other components or operations may be added. Alternatively or additionally, the plurality of components (for example, a module or a program) may be combined into one component

In this case, the combined component may perform one or more functions of each of the plurality of components identically or similarly to those performed by the corresponding component among the plurality of components prior to the combination. According to various exemplary embodiments, operations performed by a module, program, or other components may be executed sequentially, in parallel, repeatedly, or heuristically, or one or more of the operations may be executed in a different order or omitted, or one or more other operations may be added.

While this invention has been described in connection with what is presently considered to be practical exemplary embodiments, it is to be understood that the invention is not limited to the disclosed exemplary embodiments.

1. A golf simulation method comprising:
displaying an image of a first view of a green of a virtual golf course;
displaying an image of a second view of the green having a viewpoint different from the first view; and
receiving a selection of one point on the green in the image of the first view or the image of the second view.

2. The golf simulation method of claim 1, wherein:
the first view and the second view include two different views from
a top view of the green,
a view looking at a hole cup on the green from a first point on the green,
a view looking at the hole cup from a second point located opposite the first point with respect to the hole cup along an extension line connecting the first point and the hole cup, and
a view looking at the first point and the hole cup from a third point forming a predetermined angle with the extension line with respect to the hole cup.

3. The golf simulation method of claim 2, wherein:
the first view and/or the second view includes a view at a first height or a second height with respect to the ground at each point.

4. The golf simulation method of claim 1, wherein:
the first view and/or the second view further display a grid pattern on the green.

5. The golf simulation method of claim 1, further comprising:
calculating a result of an evaluation for the one point on the green.

6. The golf simulation method of claim 5, wherein:
the calculating of the result of the evaluation for the one point on the green includes:
performing a simulation in which a golf ball on the green is holed into a hole cup, and determining whether a trajectory of the golf ball calculated from the simulation passes through the one point on the green; and
determining, when the trajectory of the golf ball passes through the one point on the green, whether a direction of travel of the golf ball changes at or near the one point on the green.

7. The golf simulation method of claim 5, further comprising:
calculating a target distance from a golf ball on the green to the one point on the green.

8. The golf simulation method of claim 5, further comprising:
displaying an image of a view looking at the one point on the green from a golf ball on the green;
sensing a golf ball putted by a user;
determining a movement of the sensed golf ball; and
simulating a golf ball on the green based on the movement of the sensed golf ball.

9. An electronic apparatus comprising:
a display unit;
a user input unit; and
a control unit for displaying an image of a first view of a green of a virtual golf course on the display unit, displaying an image of a second view of the green having a viewpoint different from the first view on the display unit, and receiving a selection of one point on the green in the image of the first view or the image of the second view through the user input unit.

10. The electronic apparatus of claim 9, wherein:
the first view and the second view include two different views from
a top view of the green,
a view looking at a hole cup on the green from a first point on the green,
a view looking at the hole cup from a second point located opposite the first point with respect to the hole cup along an extension line connecting the first point and the hole cup, and
a view looking at the first point and the hole cup from a third point forming a predetermined angle with the extension line with respect to the hole cup.

11. The electronic apparatus of claim 10, wherein:
the first view and/or the second view includes a view at a first height or a second height with respect to the ground at each point.

12. The electronic apparatus of claim 9, wherein:
the first view and/or the second view further display a grid pattern on the green.

13. The electronic apparatus of claim 9, wherein:
the control unit calculates a result of an evaluation for one point on the green.

14. The electronic apparatus of claim 13, wherein:
the control unit performs performing a simulation in which a golf ball on the green is holed into a hole cup, and determines whether a trajectory of the golf ball calculated from the simulation passes through the one point on the green, and determines, when the trajectory of the golf ball passes through the one point on the green, whether a direction of travel of the golf ball changes at or near the one point on the green, to calculate the result of the evaluation.

15. The electronic apparatus of claim 13, wherein:
the control unit calculates a target distance from a golf ball on the green to the one point on the green.

16. The electronic apparatus of claim 13, wherein:
the control unit displays an image of a view looking at the one point on the green from a golf ball on the green.

17. The electronic apparatus of claim 16, further comprising:
a sensing unit for sensing a golf ball putted by a user,
wherein the control unit determines a movement of the sensed golf ball, and simulates a golf ball on the green based on the movement of the sensed golf ball.

18. A server including a communication unit, a memory, and a control unit,
wherein the control unit executes instructions stored in the memory to perform the method according to claim 1, and displays the executed instructions on an electronic apparatus communicating through the communication unit.
